(19) United States
(12) Patent Application Publication
(10) Pub. No.: US 2026/0239990 A1
(43) Pub. Date: Aug. 13, 2026

(54) EMBEDDED GRID ARRAY INDUCTOR

(71) Applicant: Arm Limited, Cambridge (GB)

(72) Inventors: Yimajian Yan, Santa Clara, CA (US); George John Scott, Chandler, AZ (US)

(21) Appl. No.: 19/053,355

(22) Filed: Feb. 13, 2025

(51) Int. Cl. H01L 23/64; H01L 23/00; H01L 25/16; H10D 80/30

(52) U.S. Cl. CPC H10W 44/501; H10D 80/30; H10W 90/00; H10W 72/248; H10W 74/15; H10W 90/724; H10W 90/734

(57) ABSTRACT

An integrated circuit assembly comprises a substrate and a grid array of electrical connections such as solder bumps formed on the surface of the substrate. An electromagnetically permeable material is formed in a closed path and disposed on the surface of the substrate, disposed at least partially within the grid array of electrical connections and encircling at least one electrical connection of the grid array of electrical connections. The electromagnetically permeable material may comprise an inductor, and may be a paramagnetic material, a ferrite material, a metal wire material, or other such material. The electromagnetically permeable material may encircle at least one solder bump of the grid array of solder bumps carrying a power signal between the substrate and the integrated circuit. The electromagnetically permeable material may be disposed on a portion of the substrate over which the solder bumps are absent from the grid array of solder bumps.

### FIELD

The field relates to packaging and powering integrated circuit devices, and more specifically to an embedded grid array inductor.

### BACKGROUND

Modern computerized devices process and store information in a variety of ways, including using processors that may have multiple cores and cache memory that may be associated with each of at least some of the processor cores. The processors in modern high-performance consumer electronics devices such as smart phones, tablet computers, set top boxes, and the like, may have different processor cores with different capabilities, such as high-performance processor cores that can perform a high number of operations per second but that may consume a significant amount of power, and efficient cores that may perform tasks more efficiently but at a lower peak number of instructions per second than high performance cores. In some further examples, at least some of the high-performance cores and/or efficient cores may have configurable performance levels, such as underdriven or overdriven voltage levels and corresponding faster or reduced operating speeds.

Processor cores in some examples may be powered up or down as needed, and in further examples may have one or more different available performance levels (and associated efficiency levels) per core. For example, a demanding video game involving rendering many objects in real time may use both high-performance cores and all the high-efficiency cores in a smartphone, while a simple task like reading email may use a single high-efficiency core. Cores may therefore be selectively powered up or selectively employed to process program instructions depending on the task load in a computing device, typically involving significant changes in power demand as different processor cores are made active or employed to process instructions.

A large integrated circuit die may also have variances in semiconductor behavior across the die or between dies (sometimes known as process corner variances), and voltages needed for different clock frequencies or performance levels of different cores may also vary significantly. Individual control of voltages for each processor core or group of processor cores is therefore desirable in some multi-core computing systems to minimize power consumption by providing each core with no more than the voltage required for reliable operation at a given performance level or clock frequency. High granularity of voltage level provided to different processor cores in a computing system via voltage regulation external to the integrated circuit die may simplify power delivery to the die, but may present challenges related to the physical wire distance and impedance between the voltage regulator and the integrated circuit die.

Multi-core processors in modern computing systems may also have their own cache memory, such as a dedicated level one (L1) or level two (L2) cache memory associated with some or all of the respective processor cores in the multi-core processor. L1 or L2 cache local to one or more processor cores may store frequently-used data local to the respective cores, which may make retrieval of this often-used data faster than if the same data was retrieved from Level 3 (L3) cache or main memory (or DRAM) that is typically slower and physically more remote. Cache memory may typically contain tens of thousands or hundreds of thousands (or more) of words of data per core, comprising a significant percentage of the die area, transistor count, and power consumed by the integrated device, and may be powered up and down or switched between active and inactive power states as processor cores are powered up and down.

When processor cores are powered on to provide greater computing resources for a computing system, they may quickly draw significantly more current than before the cores and cache were powered, potentially causing transients in voltage provided to the processor circuits. High-performance application such as servers configured to process artificial intelligence workloads may further contain thousands of cores, including hundreds of cores per integrated circuit, drawing power exceeding a kilowatt. Providing power to such cores through a voltage regulator on a motherboard may present some difficulty due to the physical distance and impedance between the voltage regulator circuitry and the integrated circuit die. Voltage regulators are often therefore designed to provide high current capability to an integrated circuit die while limiting voltage transients such as voltage spikes, voltage signal noise, and voltage droop. But, power supply circuitry may be slow to respond due to factors such as physical distance and impedance between the power supply circuitry and integrated circuit. For reasons such as these, a need exists for improved voltage stability in powering integrated circuits such as processor cores and associated cache memory.

### BRIEF DESCRIPTION OF THE DRAWINGS

The claims provided in this application are not limited by the examples provided in the specification or drawings, but their organization and/or method of operation, together with features, and/or advantages may be best understood by reference to the examples provided in the following detailed description and in the drawings, in which:

FIG. 1 is a diagram of an array of solder bumps having an electromagnetically permeable inductive material disposed therein, consistent with an example embodiment.

FIG. 2 is a side view of an inductor mounted to a substrate between an integrated circuit die and the substrate, consistent with an example embodiment.

FIG. 3 is a side view of an inductor mounted to a voltage regulator integrated circuit die between the voltage regulator integrated circuit die and a substrate, consistent with an example embodiment.

FIG. 4 shows a ball grid array having two inductors coupled to one another, each inductor encircling a group of electrical contacts, consistent with an example embodiment.

FIG. 5 shows a ball grid array having multiple embedded inductors encircling electrical connections having a different pitch and size, consistent with an example embodiment.

FIG. 6 is a flow diagram of a method of forming an array of solder joints having an electromagnetically permeable inductive material disposed therein, consistent with an example embodiment.

FIG. 7 shows a block diagram of a general-purpose computerized system, consistent with an example embodiment.

Reference is made in the following detailed description to accompanying drawings, which form a part hereof, wherein like numerals may designate like parts throughout that are corresponding and/or analogous. The figures have not necessarily been drawn to scale, such as for simplicity and/or clarity of illustration. For example, dimensions of some aspects may be exaggerated relative to others. Other embodiments may be utilized, and structural and/or other changes may be made without departing from what is claimed. Directions and/or references, for example, such as up, down, top, bottom, and so on, may be used to facilitate discussion of drawings and are not intended to restrict application of claimed subject matter. The following detailed description therefore does not limit the claimed subject matter and/or equivalents.

### DETAILED DESCRIPTION

In the following detailed description of example embodiments, reference is made to specific example embodiments by way of drawings and illustrations. These examples are described in sufficient detail to enable those skilled in the art to practice what is described, and serve to illustrate how elements of these examples may be applied to various purposes or embodiments. Other embodiments exist, and logical, mechanical, electrical, and other changes may be made.

Features or limitations of various embodiments described herein, however important to the example embodiments in which they are incorporated, do not limit other embodiments, and any reference to the elements, operation, and application of the examples serve only to aid in understanding these example embodiments. Features or elements shown in various examples described herein can be combined in ways other than shown in the examples, and any such combinations is explicitly contemplated to be within the scope of the examples presented here. The following detailed description does not, therefore, limit the scope of what is claimed.

Many modern computing systems employ processors with multiple processing cores, such that certain tasks that can be performed in parallel can be distributed among the cores for faster execution or different tasks can be performed simultaneously by different processors. Simple tasks such as checking an email may only use one processor core, while more complex tasks such as rendering a video game in real time may use all available cores. The processor cores in further examples may be associated with cache memory local to one or more of the respective processor cores, operable to store information that the processor core is likely to need for executing program instructions using local SRAM for fast access.

In some examples the different processor cores may also include different types of circuits, such as high performance processor cores, high efficiency processor cores, memory, and other such circuits. These circuits may vary in power demand, in physical location on the die, and on power demand per unit of area on the die. Powering processor cores and their related caches up and down changes the current drawn from the power source for the processor cores (and, in some further examples, associated cache memory), and may cause a temporary changes in supplied voltage while the voltage regulator or other power supply components recover from the changed demand for power. These voltage transients may be controlled to some degree using methods such as a low-dropout voltage regulator that responds somewhat quickly to changes in drawn current, by using bypass capacitors and/or inductors to store extra charge that is available to help meet a sudden demand for additional current, or through other such means. But, the impedance of solutions such as low-dropout voltage regulators or capacitors and the distance between the integrated circuit die and power components such as inductors, capacitors, and voltage regulators may limit their ability to respond quickly to changes in power demand. Problems such as these may be exacerbated by high-performance or high-density integrated circuit devices, such as integrated circuits holding hundreds of processor cores for machine learning processing that may consume hundreds or thousands of watts of power.

Some examples presented herein therefore provide for an improved inductor assembly for integrated circuit dies and packages, comprising an inductor that may be physically located between an integrated circuit die and a package substrate. In a further example, the inductor comprises an electromagnetically permeable material such as a paramagnetic material, a ferrite material, or a metal wire mounted between the integrated circuit die and a substrate in an area where connections such as pins, solder bumps, or the like may be removed or absent from a connector grid array. In a further example, the inductor may encircle one or more connections between the integrated circuit die and the substrate, such as to filter high frequency noise or voltage transients from a power signal being delivered via the one or more encircled connections.

In one such example, an integrated circuit assembly comprises a substrate and a grid array of solder joints formed on the surface of the substrate. An electromagnetically permeable material is formed in a closed path at least partially within the grid array of solder joints and encircling at least one solder joints of the grid array of solder bumps. The electromagnetically permeable material in further examples comprises an inductor, and may be a paramagnetic material, a ferrite material, a metal wire material, or other such material. The electromagnetically permeable material in some examples encircles at least one solder joint of the grid array of solder bumps carrying a power signal between the substrate and the integrated circuit. In some examples, the electromagnetically permeable material is disposed on a portion of the substrate over which the solder joints are absent from the grid array of solder joints.

In another example, a method of forming an integrated circuit assembly comprises forming a substrate, and depositing a grid array of solder joints on a surface of the substrate. An electromagnetically permeable material is formed in a closed path at least partially within the grid array of solder joints and encircling at least one solder joint of the grid array of solder joints. In another example, an integrated circuit assembly comprises a substrate and a grid array of solder joints formed on a surface of the substrate. An inductive material is formed in a closed path and disposed at least partially within the grid array of solder bumps and encircling at least one solder joints of the grid array of solder bumps. A voltage regulator circuit is mounted to the the grid array of solder joints on a first side of the substrate, the voltage regulator circuit having at least one power connection through at least one solder joint encircled by the inductive material, and an integrated circuit die is mounted to the opposite the first side of the substrate and powered at least in part by the voltage regulator circuit.

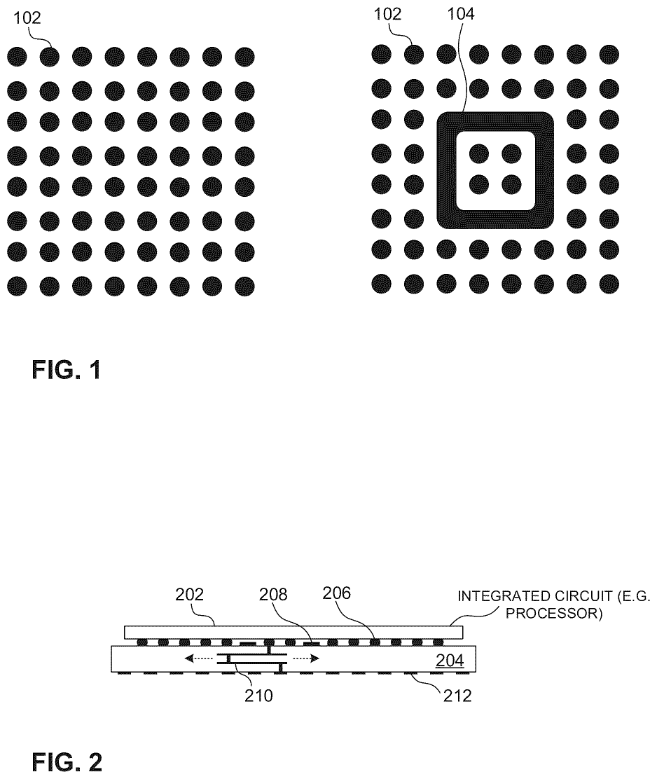

FIG. 1 is a diagram of an array of solder bumps having an electromagnetically permeable inductive material disposed therein, consistent with an example embodiment. Here, a grid array of solder bumps is shown generally at 102. The grid array in some examples may be known in the art as a ball grid array or BGA, as is commonly used as an electrical and physical interface between circuit components such as an integrated circuit package and a substrate, an interposer and a substrate, or the like. Ball grid arrays are often used to permanently mount devices such as microprocessors to circuit boards where a large number of contacts between the integrated circuit device and other circuitry are needed, such as where a flat package or dual in-line package are not sufficient. Further, a ball grid array interconnect typically has shorter traces between the solder balls or joints in the array and the integrated circuit than other packages such as a flat package, potentially providing improved high speed performance. In alternate examples, the grid array 102 may be a grid array of pins (known as a pin grid array or PGA), which may be soldered to a circuit board or removably captured by a socket, or another type of electrical and/or physical connection arranged in an array or a grid.

Arrays of solder joints may be formed in some examples by forming metal pads and adhering solder balls to the pads on either the integrated circuit package, the substrate, or both. The arrays may be in a grid pattern, such as a square grid, diagonal grid, or other such grid pattern that is desirably uniform and repeatable or standardized, such that different entities such as integrated circuit manufacturers and product circuit board manufacturers can easily produce matching or interfacing grid arrays. Solder balls may be placed using automated equipment, and may be held in place by flux before being flowed or melted into adherence with the pads such as with a reflow oven or infrared heater. Surface tension may cause molten solder to hold an integrated circuit package in alignment with the substrate during a heating cycle, holding the integrated circuit package and substrate at a desired distance apart. When the solder balls cool, the solder balls form physical and electrical joint coupling the integrated circuit and substrate.

The ball grid array as shown in FIG. 1 may be further used to mount multiple integrated circuit packages to an interposer, such as where multiple integrated circuit dies are mounted to the same substrate, but each integrated circuit die is mounted to its own interposer which is itself mounted to the substrate. The ball grid array, once reflowed to mount one layer to another, may further be filled with an underfill material filling gaps between solder joints in the ball grid array. This underfill may prevent thermal stress from heating and cooling between the integrated circuit die and the substrate such as due to differences in coefficient of thermal expansion, and may protect the inductor 104 mounted between the integrated circuit die and the substrate or between the interposer and the substrate. In further examples, a protective package covering the top of the integrated circuit die may be employed to provide thermal conductivity to a heat sink for the integrated circuit die, and an array of external electrical contacts, and/or other such components may be employed.

The integrated circuit may in various embodiments comprise various digital analog, or mixed circuits. Digital circuit examples include one or more processor cores, graphics processors, memory, signal processors, and other digital circuits, while analog circuit examples include amplifiers, filters, analog communication circuits, and the like. Mixed signal integrated circuits may contain both digital and analog circuits on the same device, such as a wireless networking integrated circuit operable to process both analog radio waves and digital data signals to facilitate transmission and/or reception of digital data using analog radio waves. The substrate in various examples may comprise a fiberglass and resin, organic laminate, ceramic, or other suitable material, and may contain within one or more conductive layers comprising various signal, power, and other electrical interconnects coupling the flip-chip bumps to ball grid array (BGA) solder balls, Land Grid Array (LGA) contact pads, Pin Grid Array pins, or other package electrical connections.

The inductor 104 in this example may be a standalone inductive ring or loop in some examples, or may be electrically coupled to a circuit such as a voltage regulator or to the integrated circuit die via one or more electrical connections such as solder bumps 102. The inductor in some embodiments may be coupled to a power supply signal powering the integrated circuit die, such as a power supply signal for one or more high performance processor cores, to store energy to be released during voltage transients such as voltage droop experienced when increasing the current drawn from the power supply signal or to reduce high frequency or switching noise in a power signal delivered to the integrated circuit. In further examples, the inductor may be augmented by one or more additional power supply components, such as a voltage regulator, a DC to DC voltage converter, and one or more capacitors. These power supply components may be physically large relative to other electronic components on or near the integrated circuit die 102, and so are external to the integrated circuit die but may desirably be physically near the integrated circuit die to reduce impedance and physical distance between the inductor 104 and the integrated circuit die to improve responsiveness to voltage transients or noise. By mounting the inductor between the integrated circuit die and the substrate, electrical connections between the power supply and the integrated circuit die's circuitry are relatively short and low impedance but still benefit from a relatively large inductor, providing fast and efficient response to voltage transients or voltage noise.

In other examples, the inductor 104 comprises an electromagnetic material such as a ferrite material or paramagnetic material that provides an inductive effect to one or more electrical connections encircled by the electromagnetic material. The material may be described in some examples as an electromagnetically permeable material, in which the electromagnetic permeability of the material measures higher than free air by at least a desired factor such as 10×, 50×, 100×, 1000×, or the like. In a more detailed example, changes in electrical current in an electrical conductor encircled by the electomagnetically permeable material such as a ferrite loop cause a change in magnetic field surrounding the electrical conductor, resulting in large eddy currents in the electromagnetically permeable material that resist the change in current in the electrical conductor. This inductive effect can reduce voltage transients or voltage oscillation in a power signal as a result of changes in power demand, can filter high frequency noise such as switching noise from a power supply signal, can filter high frequency noise from a data signal, or can perform other functions or a combination of functions such as these.

The ball grid array 102 shown in FIG. 1 may couple an integrated circuit die to a substrate or may couple a substrate to another substrate such as an interposer or a printed circuit board in various embodiments. Such configurations enable positioning an inductor 104 not only between the integrated circuit die and the substrate, but in a position surrounding one or more electrical connections such as solder balls or joints of the ball grid array. The inductor may therefore be employed in some embodiments to reduce voltage transients or noise on power delivery connections encircled by the inductor 104, or to reduce high frequency noise or other such interference on signal pins encircled by the inductor 104 such as noisy input signals from a network cable connection. Placing inductor 104 physically near the electrical connections encircled by the inductor and physically near devices connected via the grid array 102 may provide significant benefits in some examples, such as where rapid power signal support during changed power demand in an integrated circuit is desired.

FIG. 2 is a side view of an inductor mounted to a substrate between an integrated circuit die and the substrate, consistent with an example embodiment. An integrated circuit die or “chip” is shown at 202, and is attached electrically and physically to a substrate 204 by a ball grid array 206. The ball grid array (BGA) comprises in this example an array of solder balls or solder joints 206 in contact with metal conductive pads on the integrated circuit and substrate, and are reflowed or melted to electrically and physically connect the integrated circuit die to the substrate. In a more detailed example, the integrated circuit die 202 is attached to the substrate 204 such as using a flip chip ball grid array (FCBGA) and underfill material such as epoxy to reduce stress on the ball grid array solder joints 206 due to differing coefficients of thermal expansion between the integrated circuit die 202 and the substrate 204.

An inductor 208 is further embedded within the ball grid array, which in some examples involves removing one or more solder bumps or joints and their corresponding electrical contact points on the integrated circuit die and/or the substrate from the ball grid array to physically accommodate the inductor as is shown in the example of FIG. 1. The inductor in some examples encircles one or more electrical connections such as ball grid array solder joints 206, providing inductive impedance to rapid changes in current flow or filtering high frequency noise from the electrical connections, such as power delivery electrical connections, data signal electrical connections, and the like. The inductor 208 in the example of FIG. 2 is physically mounted to the substrate 204, but in other examples may be mounted to the integrated circuit die 202 or otherwise mounted between the integrated circuit die and the substrate.

One or more electrical connections and/or vias 210 in substrate 204 may further couple the electrical connections such as solder joints 206 between the integrated circuit die 202 and substrate 204 to electrical connections 212 on a side of the substrate opposite the integrated circuit, such as for connection to a printed circuit board or the like. The electrical connections 210 in other examples may distribute signals such as power signals to one or more electrical connections to the integrated circuit 202, may couple the integrated circuit 202 to one or more external components such as a voltage regulator or the inductor 208, or may provide other such electrical connections. In a further example, the inductor 208 may comprise a wire wound inductor that is coupled to a voltage regulator circuit, or may comprise an inductor having electrical connections that are coupled to another circuit. In alternate examples, the inductor 208 may be a closed inductor, such as an inductor coupled only to itself or to a terminating resistor or the like. The inductor 208 in other examples may comprise an electromagnetically permeable or inductive material, such as a ferrite ring, a paramagnetic material, or other such material.

In some embodiments, the inductor may be embedded in a cavity or opening in substrate 204, such as to increase the amount of available space between the substrate 204 and the integrated circuit 202 for the inductor 208. In some such embodiments, the cavity or opening does not extend entirely through substrate 204, leaving substrate 204 intact through at least some layers such as to provide for electrical connections 210 to route electrical signals such as power signals or data signals to one or more solder joints 206 encircled by inductor 208. Such a cavity may be formed in the substrate using laser or other energy etching, grinding or other mechanical ablation, chemical removal, lamination of substrate layers having different profiles, or other suitable methods in various embodiments. The cavity in some examples may be larger than the physical dimensions of the inductor, such as at least 10 microns wider in each dimension than the capacitor, to allow the inductor to be easily received in the cavity without unnecessarily strict tolerance requirements or pressure fitting the inductor to the cavity.

In another example, the substrate 204 may be an interposer that resides between an integrated circuit die 202 and another substrate below 204, such as may be used with multi-chip modules, multiple processor modules, or the like. In further examples, inductor 208 may reside within a grid array coupling an interposer and a substrate rather than between an integrated circuit die and a substrate. The gap between integrated circuit 202 and the substrate 204 in various embodiments may also be filled with an underfill such as epoxy, such as to reduce stress on solder joints 206 from different coefficients of thermal expansion between the integrated circuit die 202, the substrate 204, and inductor 208, and to keep inductor 208 positioned in place.

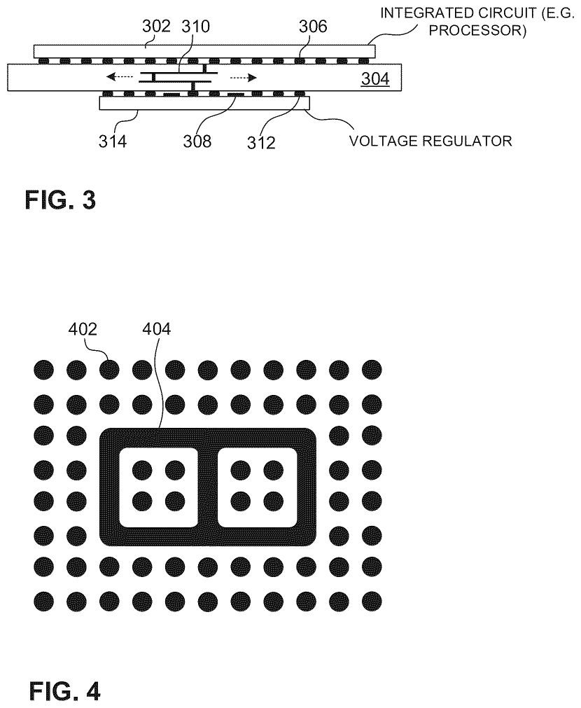

FIG. 3 is a side view of an inductor mounted to a voltage regulator integrated circuit die between the voltage regulator integrated circuit die and a substrate, consistent with an example embodiment. Here, an integrated circuit die 302 is mounted to a substrate 304 using a ball grid array of solder ball joints 306, such as in the example of FIG. 2. Electrical connections and vias 310 in substrate 304 again provide for one or more electrical connections between the integrated circuit die and the substrate. A voltage regulator integrated circuit 314 is coupled to the substrate via a solder ball array 312, such that one or more solder balls 312 coupling the voltage regulator integrated circuit 314 to the substrate 304 to power the integrated circuit 302 are encircled by the inductor 308. The inductor 308 may therefore provide a filtering effect on high frequency current changes in signals carried in the encircled electrical connections. In some further examples, the inductor 308 may have one or more electrical connections to the voltage regulator integrated circuit die 314, such as integrating the inductor into voltage regulator circuitry on voltage regulator integrated circuit die 314 or otherwise coupling the inductor to a circuit for the benefit of one or more circuits on the integrated circuit die 302.

In the example of FIG. 3, the inductor is physically attached or mounted to the integrated circuit die 314 between the substrate 304 and the voltage regulator integrated circuit die. In other examples, the inductor may be mounted to substrate 304 between the substrate 304 and the voltage regulator integrated circuit die 314, to the substrate between the substrate 304 and the integrated circuit die 302, or to the integrated circuit die 302 between the integrated circuit die 302 and the substrate 304.

FIG. 4 shows a ball grid array having two inductors coupled to one another, each inductor encircling a group of electrical contacts, consistent with an example embodiment. Here, the ball grid array of solder ball joints 402 have an inductor 404 embedded therein that comprises two separate loops, with each loop encircling a different group of four electrical connections between an integrated circuit and a substrate. The two separate loops may in various examples encircle connectors carrying different power or data signals, such as one loop encircling a primary power supply group of signals and another loop encircling ground signa connections. In an alternate embodiment, separate inductive loops may encircle different conductors in the same power supply circuit, such as one loop encircling voltage supply connections and another loop encircling data signal connections. In further examples, more than two electromagnetic material inductive loops may be shown, such as where an integrated circuit die receives a number of different power signals at different voltages or different groups of data signals such as multiple network interfaces. In one such example, a mixed signal processing integrated circuit receives both digital and analog power signals, and uses separate inductive loops for both power signals. In another such example, different processor cores on an integrated circuit operate at different performance levels and different voltages supplied by different power signals, two or more of which may be encircled by separate inductive loops.

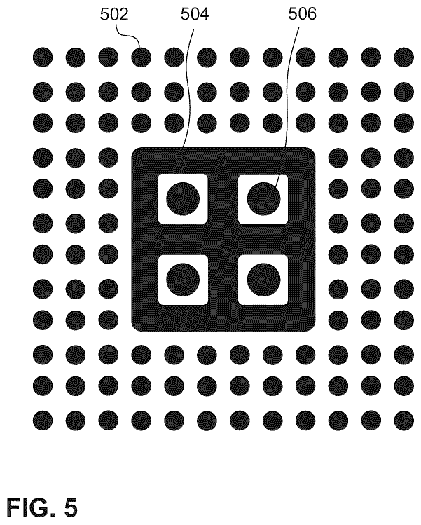

FIG. 5 shows a ball grid array having multiple embedded inductors encircling electrical connections having a different pitch and size, consistent with an example embodiment. Here, a grid array 502 of solder bump connections, such as a ball grid array on an integrated circuit die or a substrate, has an electromagnetically permeable inductor 504 such as an inductive material ring in a closed circular loop, rectangular loop, or the like embedded within the array. The inductor 504 in this example comprises four separate loop inductors, each sharing two sides with a neighboring inductor. In other examples, separate inductors may be physically separate from one another such that they are not in physical contact with one another and do not carry significant electric or magnetic conduction between loops.

The four inductor loops shown at 504 in this example each encircle an electrical connection 506, which in this example comprise larger solder bumps than the solder balls or joints forming ball grid array 502. The larger solder joints 506 in this example may be desirably larger than the solder joint connections in ball grid array 502 because they carry power signals that benefit from a larger size connector, such as to improve current handling capability or to provide a lower connection impedance. The pitch or distance between encircled solder joints 506 in this example is also larger than the pitch between solder joints in the ball grid array 502, potentially allowing for larger inductor loops 504 or allowing for greater tolerance in reflowing larger bumps such as to provide greater clearance between the solder bumps and the encircled solder bumps. Because power demand for integrated circuits continues to climb into the hundreds of watts or more per integrated circuit device, larger power connectors and inductors may be of benefit in many examples.

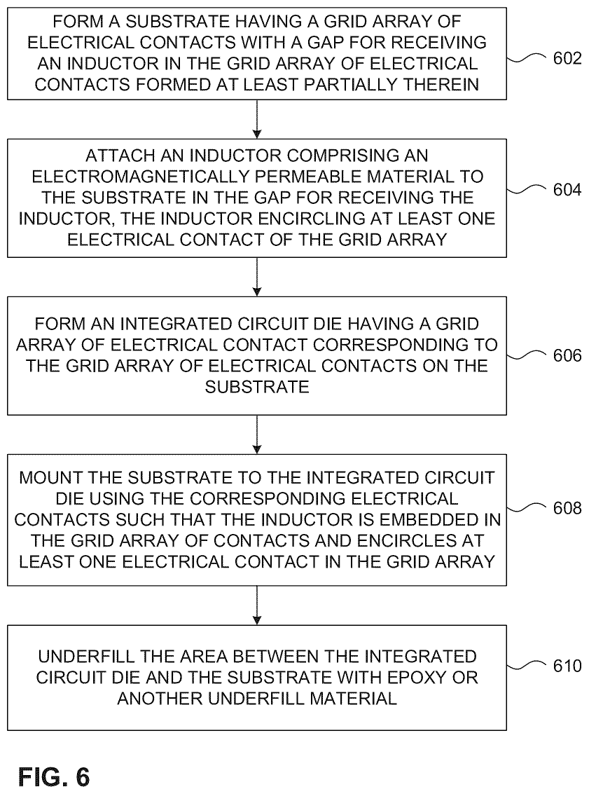

FIG. 6 is a flow diagram of a method of forming an array of solder joints having an electromagnetically permeable inductive material disposed therein, consistent with an example embodiment. In the example of FIG. 6, an inductor comprising an electromagnetically permeable material is embedded on a substrate, between the substrate an integrated circuit at least partially within a grid array of electrical contacts. In other examples, an electromagnetically permeable inductor may be embedded on an integrated circuit die, an interposer, a printed circuit board, or the like within an array of electrical contacts, such as on a substrate between the substrate and integrated circuit die or between an interposer and a substrate. The electromagnetically permeable inductor material may be formed at least partially within the grid array of electrical contacts, and in various embodiments may encircle one or more electrical contacts that are a part of the grid array or that are within the grid array.

In the example of FIG. 6, a substrate is formed at 602, having a grid array of electrical contacts. The electrical contacts in various examples may be arranged in a grid, array, or other such pattern, and may comprise various forms of electrical contacts such as a ball grid array (BGA), a pin grid array (PGA), or other such array of contacts. The grid array of contacts is configured to accommodate an inductor at least partially within the grid array, such as by having a gap in contacts for accommodating an inductor as is shown in various examples and figures presented herein. In further examples, the array of contacts may have different contacts such as for mounting the inductor, guides for aligning the inductor when mounting, or the like. An inductor comprising an electromagnetically permeable material is formed and is attached to the substrate at 604, configured to reside in the gap or other accommodation for the inductor in the grid array of electrical contacts. In some examples, a cavity or opening may be formed in the substrate to better accommodate inductors of greater thickness or size. The inductor may be at least partially embedded within the grid array of electrical contacts, and may encircle at least one electrical contact for which it may be configured to provide inductive filtering such as filtering out high frequency noise or supporting current flow during rapid changes in demand from an integrated circuit.

An integrated circuit die is formed 606, having a grid array of electrical contacts corresponding to the grid array of electrical contacts on the substrate. In a more detailed example, this may include a gap in the array of electrical contacts for accommodating the inductor, and one or more other accommodations such as were described with respect to the accommodation examples for the substrate. At 608, the integrated circuit die and the substrate with the inductor mounted to it are mounted together, such as by reflowing solder balls in a ball grid array, inserting the integrated circuit pins into a socket or plated through holes in a pin grid array, or the like. Once the integrated circuit is mounted to the substrate, at least one electrical joint between the integrated circuit and the substrate may be encircled by the inductor embedded in the grid array of electrical contacts such as is shown in the examples of FIGS. 1-5.

The area between the integrated circuit die and the substrate that is not occupied by the grid array of electrical joints or by the inductor may be filled with an underfill material such as epoxy at 610. The underfill in various examples may comprise a paste, a film, a capillary flow or pressurized liquid, or another suitable material. The material in various examples may be epoxy, or another suitable resin, or a curable polymer, such that the material may effectively eliminate or substantially reduce air gaps between the integrated circuit die, the capacitor, and the substrate. The underfill material may also bind the integrated circuit die and the substrate together, reducing stress on electrical contacts as a result of differences in coefficient of thermal expansion between the integrated circuit die and the substrate, such as during reflow or other changes in temperature.

In some further examples, an interposer may be situated between the integrated circuit die and the substrate, such as to accommodate more than one integrated circuit die or additional components that are to be coupled to the substrate. In one such example, an interposer may be formed between steps 604 and 606, such that the interposer has a grid array of electrical contacts corresponding to the integrated circuit die and/or the substrate, which may be configured to accommodate an inductor mounted within the array of electrical contacts. The interposer may be mounted to the substrate and the integrated circuit die may be mounted to the interposer, such that the interposer is “sandwiched” between the substrate and the integrated circuit die. The inductor in various such examples may be physically mounted to the integrated circuit, the interposer, or the substrate.

The examples presented herein illustrate how a an inductor may be positioned physically between an integrated circuit die and a substrate within an array of electrical contacts and encircle one or more electrical contacts within the array. The inductor in various examples may be wire, ferrite, or another electromagnetically permeable material, and may be closed or part of a circuit. The array of electrical contacts may be a ball grid array, pin grid array, or other array in various examples. The inductor may serve to filter high frequency noise from an electrical signal encircled by the inductor, provide inductive support for current flow in the inductor during periods of power demand transition, and/or perform other such functions. The inductor may be placed physically very near the integrated circuit by being embedded between the integrated circuit and the substrate, providing rapid response to signal changes in the encircled electrical connections such as rapid changes in power demand.

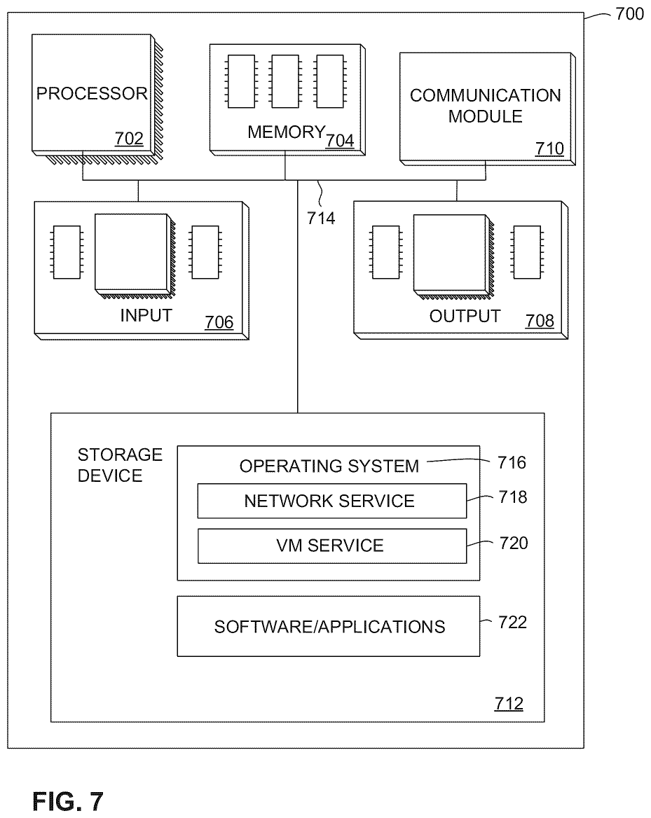

FIG. 7 shows a block diagram of a general-purpose computerized system, consistent with an example embodiment. FIG. 7 illustrates only one particular example of computing device 700, and other computing devices 700 may be used in other embodiments. Although computing device 700 is shown as a standalone computing device, computing device 700 may be any component or system that includes one or more processors or another suitable computing environment for executing software instructions in other examples, and need not include all of the elements shown here.

As shown in the specific example of FIG. 7, computing device 700 includes one or more processors 702, memory 704, one or more input devices 706, one or more output devices 708, one or more communication modules 710, and one or more storage devices 712. Computing device 700, in one example, further includes an operating system 716 executable by computing device 700. The operating system includes in various examples services such as a network service 718 and a virtual machine service 720 such as a virtual server. One or more applications, such as application 722 are also stored on storage device 712, and are executable by computing device 700.

Each of components 702, 704, 706, 708, 710, and 712 may be interconnected (physically, communicatively, and/or operatively) for inter-component communications, such as via one or more communications channels 714. In some examples, communication channels 714 include a system bus, network connection, inter-processor communication network, or any other channel for communicating data. Applications such as software application 722 and operating system 916 may also communicate information with one another as well as with other components in computing device 700.

Processors 702, in one example, are configured to implement functionality and/or process instructions for execution within computing device 700. For example, processors 702 may be capable of processing instructions stored in storage device 712 or memory 704. Examples of processors 702 include any one or more of a microprocessor, a controller, a central processing unit (CPU), a graphics processing unit (GPU), a neural processing unit (NPU), an image signal processor (ISP), a digital signal processor (DSP), an application specific integrated circuit (ASIC), a field-programmable gate array (FPGA), or similar discrete or integrated logic circuitry.

One or more storage devices 712 may be configured to store information within computing device 700 during operation. Storage device 712, in some examples, is known as a computer-readable storage medium. In some examples, storage device 712 comprises temporary memory, meaning that a primary purpose of storage device 712 is not long-term storage. Storage device 712 in some examples is a volatile memory, meaning that storage device 712 does not maintain stored contents when computing device 700 is turned off. In other examples, data is loaded from storage device 712 into memory 704 during operation. Examples of volatile memories include random access memories (RAM), dynamic random access memories (DRAM), static random access memories (SRAM), and other forms of volatile memories known in the art. In some examples, storage device 712 is used to store program instructions for execution by processors 702. Storage device 712 and memory 704, in various examples, are used by software or applications running on computing device 700 such as software application 722 to temporarily store information during program execution.

Storage device 712, in some examples, includes one or more computer-readable storage media that may be configured to store larger amounts of information than volatile memory. Storage device 712 may further be configured for long-term storage of information. In some examples, storage devices 712 include non-volatile storage elements. Examples of such non-volatile storage elements include magnetic hard discs, optical discs, floppy discs, flash memories, or forms of electrically programmable memories (EPROM) or electrically erasable and programmable (EEPROM) memories.

Computing device 700, in some examples, also includes one or more communication modules 710. Computing device 700 in one example uses communication module 710 to communicate with external devices via one or more networks, such as one or more wireless networks. Communication module 710 may be a network interface card, such as an Ethernet card, an optical transceiver, a radio frequency transceiver, or any other type of device that can send and/or receive information. Other examples of such network interfaces include Bluetooth, 4G, LTE, or 5G, WiFi radios, and Near-Field Communications (NFC), and Universal Serial Bus (USB). In some examples, computing device 700 uses communication module 710 to wirelessly communicate with an external device such as via a public network.

Computing device 700 also includes in one example one or more input devices 706. Input device 706, in some examples, is configured to receive input from a user through tactile, audio, or video input. Examples of input device 706 include a touchscreen display, a mouse, a keyboard, a voice responsive system, video camera, microphone or any other type of device for detecting input from a user.

One or more output devices 708 may also be included in computing device 700. Output device 708, in some examples, is configured to provide output to a user using tactile, audio, or video stimuli. Output device 708, in one example, includes a display, a sound card, a video graphics adapter card, or any other type of device for converting a signal into an appropriate form understandable to humans or machines. Additional examples of output device 808 include a speaker, a light-emitting diode (LED) display, a liquid crystal display (LCD or OLED), or any other type of device that can generate output to a user.

Computing device 700 may include operating system 716. Operating system 716, in some examples, controls the operation of components of computing device 700, and provides an interface from various applications such as software application 722 to components of computing device 700. For example, operating system 716, in one example, facilitates the communication of various applications such as software application 722 with processors 702, communication unit 710, storage device 712, input device 706, and output device 708. Applications such as application 722 may include program instructions and/or data that are executable by computing device 700. These and other program instructions or modules may include instructions that cause computing device 700 to perform one or more of the other operations and actions described in the examples presented herein.

Process cores, bitcell arrays, memory structures, peripheral circuitry, and other circuits as described herein in particular examples may be formed in whole or in part by and/or expressed in transistors and/or lower metal interconnects (not shown) in processes (e.g., front end-of-line and/or back-end-of-line processes) such as processes to form complementary metal oxide semiconductor (CMOS) circuitry. The various blocks, neural networks, and other elements disclosed herein may be described using computer aided design tools and expressed (or represented), as data and/or instructions embodied in various computer-readable media, in terms of their behavioral, register transfer, logic component, transistor, layout geometries, and/or other characteristics.

Concepts described herein may be embodied in computer-readable code for fabrication of an apparatus that embodies the described concepts. For example, the computer-readable code can be used at one or more stages of a semiconductor design and fabrication process, including an electronic design automation (EDA) stage, to fabricate an integrated circuit comprising the apparatus embodying the concepts. The above computer-readable code may additionally or alternatively enable the definition, modelling, simulation, verification and/or testing of an apparatus embodying the concepts described herein.

For example, the computer-readable code for fabrication of an apparatus embodying the concepts described herein can be embodied in code defining a hardware description language (HDL) representation of the concepts. For example, the code may define a register-transfer-level (RTL) abstraction of one or more logic circuits for defining an apparatus embodying the concepts. The code may define a HDL representation of the one or more logic circuits embodying the apparatus in Verilog, SystemVerilog, Chisel, or VHDL (Very High-Speed Integrated Circuit Hardware Description Language) as well as intermediate representations such as FIRRTL. Computer-readable code may provide definitions embodying the concept using system-level modelling languages such as SystemC and SystemVerilog or other behavioural representations of the concepts that can be interpreted by a computer to enable simulation, functional and/or formal verification, and testing of the concepts.

Additionally or alternatively, the computer-readable code may define a low-level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying the invention. Alternatively or additionally, the one or more logic synthesis processes can generate from the computer-readable code a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying the invention. Alternatively or additionally, the concept may be defined in a combination of a computer-readable definition to be used in a semiconductor design and fabrication process to fabricate an apparatus and computer-readable code defining instructions which are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

Features of example computing devices employed in example embodiments may comprise features, for example, of a client computing device and/or a server computing device. The term computing device, in general, whether employed as a client and/or as a server, or otherwise, refers at least to a processor and a memory connected by a communication bus. A “processor” and/or “processing circuit” for example, is understood to connote a specific structure such as a central processing unit (CPU), digital signal processor (DSP), graphics processing unit (GPU), image signal processor (ISP) and/or neural processing unit (NPU), or a combination thereof, of a computing device which may include a control unit and an execution unit. In an aspect, a processor and/or processing circuit may comprise a device that fetches, interprets and executes instructions to process input signals to provide output signals. As such, in the context of the present patent application at least, this is understood to refer to sufficient structure within the meaning of 35 USC § 112 (f) so that it is specifically intended that 35 USC § 112 (f) not be implicated by use of the term “computing device,” “processor,” “processing unit,” “processing circuit” and/or similar terms; however, if it is determined, for some reason not immediately apparent, that the foregoing understanding cannot stand and that 35 USC § 112 (f), therefore, necessarily is implicated by the use of the term “computing device” and/or similar terms, then, it is intended, pursuant to that statutory section, that corresponding structure, material and/or acts for performing one or more functions be understood and be interpreted to be described at least in FIG. 1 and in the text associated with the foregoing figure(s) of the present patent application.

Some embodiments may be described, at least in part, by the following numbered clauses or by any combination thereof:
Clause 1: An assembly, comprising: a substrate; a grid array of solder joints formed on a surface of the substrate; and an electromagnetically permeable material formed in a closed path disposed at least partially within the grid array of solder joints and encircling at least one solder joint of the grid array of solder joints.
Clause 2: The assembly of clause 1, wherein the electromagnetically permeable material is disposed on a portion of the substrate over which the solder joints are absent from the grid array.
Clause 3: The assembly of any of the aforementioned clauses, wherein the electromagnetically permeable material is attached to the substrate by one or more of solder joints, an epoxy, a conformal coat, an underfill material, or a mechanical fastener.
Clause 4: The assembly of any of the aforementioned clauses, wherein the closed path further comprises two or more separately closed paths formed by the electromagnetic material.
Clause 5: The assembly of any of the aforementioned clauses, wherein the at least one solder joint of the grid array of solder joints encircled by the electromagnetically permeable material are at a different pitch than the grid array of solder joints formed on the surface of the substrate.
Clause 6: The assembly of any of the aforementioned clauses, wherein the electromagnetically permeable material is a paramagnetic or a ferromagnetic material.
Clause 7: The assembly of any of the aforementioned clauses, wherein the electromagnetically permeable material comprises a metal wire coil.
Clause 8: The assembly of clause 7, wherein the metal wire coil is further coupled to one or more additional circuit components.
Clause 9: The assembly of any of the aforementioned clauses, wherein the electromagnetically permeable material formed in a closed path is formed in a square or rectangle.
Clause 10: The assembly of any of the aforementioned clauses, wherein the electromagnetically permeable material is disposed on a surface of the substrate.
Clause 11: The assembly of any of the aforementioned clauses, further comprising an integrated circuit mounted to the substrate, the electromagnetically permeable material disposed on a portion of the integrated circuit.
Clause 12: A method, comprising: forming a substrate; depositing a grid array of solder joints on a surface of the substrate; and disposing an electromagnetically permeable material formed in a closed path disposed at least partially within the grid array of solder joints and encircling at least one solder joint of the grid array of solder joints.
Clause 13: The method of clause 12, wherein the closed path further comprises two or more separate closed paths formed by the electromagnetically permeable material.
Clause 14: The method of any of clauses 12-13, wherein the electromagnetically permeable material comprises a paramagnetic material, a ferromagnetic material, or a metal wire coil.
Clause 15: The method of any of clauses 12-14, wherein the electromagnetically permeable material formed in a closed path is formed in a square or rectangle.
Clause 16: The method of any of clauses 12-15, wherein the electromagnetically permeable material is disposed on a surface of the substrate.
Clause 17: The method of any of clauses 12-16, further comprising mounting an integrated circuit to the substrate, the electromagnetically permeable material disposed on a portion of the integrated circuit.
Clause 18: An assembly, comprising: a substrate; a grid array of solder joints formed on a surface of the substrate; an inductive material formed in a closed path, the inductive material disposed at least partially within the grid array of solder joints and encircling at least one solder joint of the grid array of solder joints; a voltage regulator circuit mounted to the the grid array of solder joints on a first side of the substrate, the voltage regulator circuit having at least one power connection through at least one solder joint encircled by the inductive material; and an integrated circuit die mounted to the opposite the first side of the substrate and powered at least in part by the voltage regulator circuit.
Clause 19: The assembly of clause 18, wherein the inductive material is disposed on a surface of the substrate.
Clause 20: The assembly of any of clauses 18-19, wherein the inductive material is disposed on a surface of the integrated circuit die or the voltage regulator circuit.

Although specific embodiments have been illustrated and described herein, any arrangement that achieve the same purpose, structure, or function may be substituted for the specific embodiments shown. This application is intended to cover any adaptations or variations of the example embodiments of the invention described herein. These and other embodiments are within the scope of the following claims and their equivalents.

What is claimed is:

1. An assembly, comprising:
a substrate;
a grid array of solder joints formed on a surface of the substrate; and
an electromagnetically permeable material formed in a closed path disposed at least partially within the grid array of solder joints and encircling at least one solder joint of the grid array of solder joints.

2. The assembly of claim 1, wherein the electromagnetically permeable material is disposed on a portion of the substrate over which the solder joints are absent from the grid array.

3. The assembly of claim 1, wherein the electromagnetically permeable material is attached to the substrate by one or more of solder joints, an epoxy, a conformal coat, an underfill material, or a mechanical fastener.

4. The assembly of claim 1, wherein the closed path further comprises two or more separately closed paths formed by the electromagnetically permeable material.

5. The assembly of claim 1, wherein the at least one solder joint of the grid array of solder joints encircled by the electromagnetically permeable material are at a different pitch than the grid array of solder joints formed on the surface of the substrate.

6. The assembly of claim 1, wherein the electromagnetically permeable material is a paramagnetic or a ferromagnetic material.

7. The assembly of claim 1, wherein the electromagnetically permeable material comprises a metal wire coil.

8. The assembly of claim 7, wherein the metal wire coil is further coupled to one or more additional circuit components.

9. The assembly of claim 1, wherein the electromagnetically permeable material formed in a closed path is formed in a polygon.

10. The assembly of claim 1, wherein the electromagnetically permeable material is disposed on a surface of the substrate.

11. The assembly of claim 1, further comprising an integrated circuit mounted to the substrate, the electromagnetically permeable material disposed on a portion of the integrated circuit.

12. A method, comprising:
forming a substrate;
depositing a grid array of solder joints on a surface of the substrate; and
disposing an electromagnetically permeable material formed in a closed path disposed at least partially within the grid array of solder joints and encircling at least one solder joint of the grid array of solder joints.

13. The method of claim 12, wherein the closed path further comprises two or more separate closed paths formed by the electromagnetically permeable material.

14. The method of claim 12, wherein the electromagnetically permeable material comprises a paramagnetic material, a ferromagnetic material, or a metal wire coil.

15. The method of claim 12, wherein the electromagnetically permeable material formed in a closed path is formed in a square or rectangle.

16. The method of claim 12, wherein the electromagnetically permeable material is disposed on a surface of the substrate.

17. The method of claim 12, further comprising mounting an integrated circuit to the substrate, the electromagnetically permeable material disposed on a portion of the integrated circuit.

18. An assembly, comprising:
a substrate;
a grid array of solder joints formed on a surface of the substrate;
an inductive material formed in a closed path, the inductive material disposed at least partially within the grid array of solder joints and encircling at least one solder joint of the grid array of solder joints;
a voltage regulator circuit mounted to the the grid array of solder joints on a first side of the substrate, the voltage regulator circuit having at least one power connection through at least one solder joint encircled by the inductive material; and
an integrated circuit die mounted to a side of the substrate opposite the first side of the substrate and powered at least in part by the voltage regulator circuit.

19. The assembly of claim 18, wherein the inductive material is disposed on a surface of the substrate.

20. The assembly of claim 18, wherein the inductive material is disposed on a surface of the integrated circuit die or the voltage regulator circuit.
